(19) United States
(12) Patent Application Publication
(10) Pub. No.: US 2013/0083048 A1
(43) Pub. Date: Apr. 4, 2013

(54) INTEGRATED CIRCUIT WITH ACTIVE MEMORY AND PASSIVE VARIABLE RESISTIVE MEMORY WITH SHARED MEMORY CONTROL LOGIC AND METHOD OF MAKING SAME

(71) Applicant: Advanced Micro Devices, Inc., Sunnyvale, CA (US)

(72) Inventor: Donald R. Weiss, Fort Collins, CO (US)

(73) Assignee: Advanced Micro Devices, Inc., Sunnyvale, CA (US)

(21) Appl. No.: 13/629,675

(22) Filed: Sep. 28, 2012

Related U.S. Application Data
(60) Provisional application No. 61/540,635, filed on Sep. 29, 2011.

(51) Int. Cl. G11C 11/34; G06T 1/60; H01L 45/00

(52) U.S. Cl. 345/555; 365/148; 438/382; 257/E45.001

(57) ABSTRACT

An integrated circuit includes, in one example, an active memory cell array and a passive variable resistance memory cell array positioned above the active memory cell array, such as in upper layers of the integrated circuit. The active memory cell array and the passive variable resistance memory cell array share one or more components of memory control logic such as address decode logic, data read logic and/or data write logic. As such, a type of active memory and passive variable resistance memory hybrid structure shares memory control logic such as word line drivers, bit line drivers and read logic. The active memory cell array and passive variable resistance memory cell array overlap reducing integrated circuit die size, improving power reduction and reducing costs by sharing peripheral circuits.

### CROSS-REFERENCE TO RELATED APPLICATION

This application claims priority to Provisional Application Ser. No. 61/540,635, filed on Sep. 29, 2011, having inventor Donald R. Weiss, titled “INTEGRATED CIRCUIT WITH ACTIVE MEMORY AND PASSIVE VARIABLE RESISTIVE MEMORY WITH SHARED MEMORY CONTROL LOGIC AND METHOD OF MAKING SAME”, which is incorporated herein by reference.

### BACKGROUND OF THE INVENTION

The disclosure relates generally to integrated circuits and more particularly to integrated circuits that contain memory, and methods for making the same.

Dynamic random access memory (DRAM) and flash memory are two dominant memory technologies generally accepted to be nearing the end of their scaling lifetime, and the search is on for a replacement that can scale beyond DRAM and flash memory, while maintaining low latency and energy efficiency. Passive variable resistance memory, also known as resistive non-volatile memory, is emerging as a ubiquitous next generation of flash replacement technology (FRT). Passive variable resistance memory includes but is not limited to memristors, phase-change memory, and magnetoresistive memory (e.g., spin-torque transfer magnetoresistive memory). A key behind the passive variable resistance memory is storing state in the form of resistance instead of charge.

Similar to DRAM and flash memory, passive variable resistance memory may be used as on-chip memory integrated with processors, such as central processing units (CPUs) or graphic processing units (GPUs), in the forms of cache memory and/or main memory. It has been proposed to place passive variable resistance memory either laterally on the same die of the processor or on a separate die connected laterally to the processor die through a circuit board. Either implementation, however, has issues with cost and distance of the memory to where it is needed on the processor. As the passive variable resistance memory and the processor are laterally arranged, the die area and packaging size may be increased, and the memory access may be slowed due to the relative long lateral connection distance.

Since there are advantages of each memory technology, there may be a need for more than one memory technology on the same integrated circuit, for example, where the integrated circuit includes a processor. For example, SRAM may be used for fast access, DRAM for low power or non-volatile memory for retention. Traditionally, these different memories were implemented in separate portions of the die because they each required the same processing layers and devices. For example, an active memory array such as SRAM or DRAM that employs active CMOS devices, may include its own address decode logic and corresponding read/write logic to access active memory cell arrays in the memory. In addition, FRT memory cell arrays may include their own separate address decode logic and corresponding data read/write logic that is located in a different portion of the die. These duplicate memory configurations adds area, cost and power consumption.

Accordingly, a need exists for an improved integrated circuit that employs both active memory cell arrays and FRT memory cell arrays.

### BRIEF DESCRIPTION OF THE DRAWINGS

The invention will be more readily understood in view of the following description when accompanied by the below figures and wherein like reference numerals represent like elements, wherein:

FIG. 1 is a block diagram illustrating one example of an embodiment employing an integrated circuit with active memory and passive variable resistance memory that share at least some peripheral circuits between the two memory cell arrays in accordance with one example set forth in the disclosure;

FIG. 2 illustrates one example of an integrated circuit in accordance with one example set forth in the disclosure;

FIG. 3 is a flowchart generally illustrating on example of a method of making an integrated circuit in accordance with one example set forth in the disclosure;

FIG. 4 is a diagram illustrating one example of an integrated circuit in accordance with one example set forth in the disclosure; and

FIG. 5 is a block diagram illustrating one example of an integrated circuit set forth in the disclosure.

### DETAILED DESCRIPTION OF THE PREFERRED EMBODIMENTS

Briefly, an integrated circuit includes, in one example, an active memory cell array and a passive variable resistance memory cell array positioned above the active memory cell array, such as in upper layers of the integrated circuit. The active memory cell array and the passive variable resistance memory cell array share one or more components of memory control logic such as address decode logic, data read logic and/or data write logic. As such, a type of active memory and passive variable resistance memory hybrid structure shares memory control logic such as word line drivers, bit line drivers and read logic. The active memory cell array and passive variable resistance memory cell array overlap reducing integrated circuit die size, improving power reduction and reducing costs by sharing peripheral circuits.

A method of making the integrated circuit is also disclosed that includes, for example, forming an active memory cell array, address decode logic, data read logic and data write logic on a substrate. The method also includes forming a passive variable resistance memory cell array in layers above the active memory cell array such that the passive variable memory cell array is configured to share at least the same address decode logic as the active memory cell array to effect an address decode operation. In one example, a metal layer also referred to as an electrode layer, is deposited between the active memory cell array and a passive variable resistance memory cell array so that a shared metal layer is used to effect address decode operations and other memory control operations between an active memory cell array and a passive variable resistance memory cell array. In one example, the active memory cell array is coupled to the address decode logic by the same metal layer coupled to the passive variable resistance memory cell array. The common metal layer is interconnected to provide a common word and/or bit line for both the active memory cell array and the passive variable resistance memory cell array.

In another example, the integrated circuit includes active memory interface logic coupled to the active memory cell array, passive variable resistance memory interface logic that is coupled to the passive variable resistance memory cell array. The integrated circuit also includes memory technology switch control logic that is operative to control the active memory interface logic, the passive variable resistance memory interface logic and the data read and write logic, to selectively provide read/write access to either the active memory cell array or the passive variable resistance memory cell array. A processor may also be included in the integrated circuit which is fabricated on the substrate that is used to support the active memory cell array, address decode logic and data read and write logic.

Among other advantages, a very high bandwidth copy mechanism between the two differing memory cell technology types can be employed that does not require outside resource and control circuits. The passive variable resistance memory cell array may also serve as a non-volatile backup storage for the contents of the active memory cell array. Other advantages will be recognized by those of ordinary skill in the art.

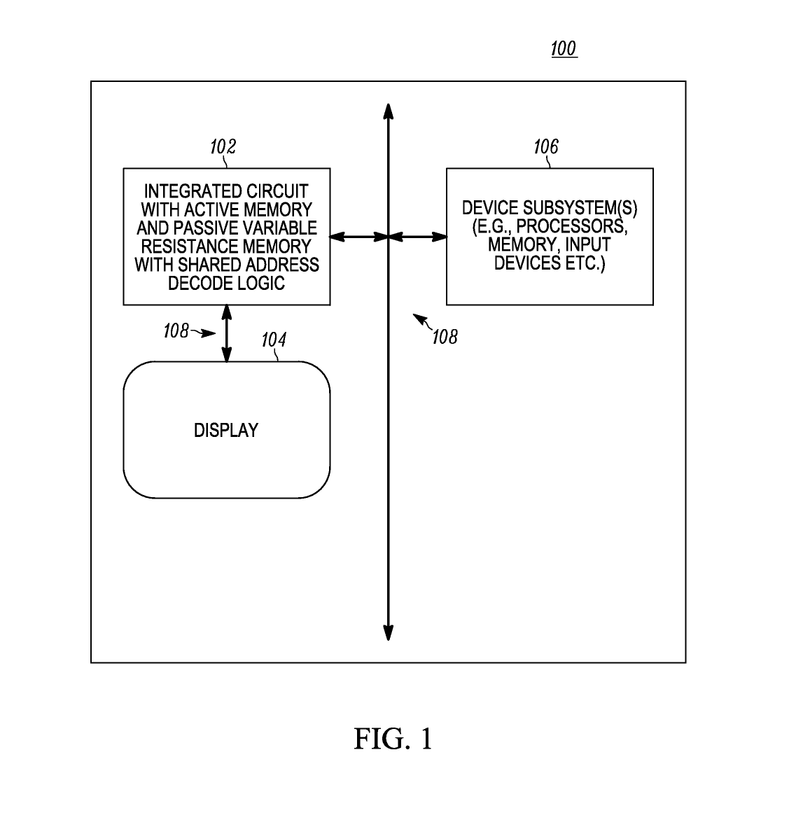

FIG. 1 illustrates one example of an apparatus 100 including an integrated circuit 102 with active memory and passive variable resistive memory that are configured to share memory control logic such one or more of address decode logic and memory read/write logic. The apparatus 100 may be any suitable device, for example, a laptop computer, desktop computer, media center, handheld device (e.g., mobile or smart phone, tablet, etc.), Blu-ray™ player, gaming console, set top box, printer, or any other suitable device. The apparatus 100 may also include a device sub-system 104 and/or a display 106 that are operatively coupled to the integrated circuit 102 via one or more suitable communication links 108 such as buses or any other suitable links. It is understood, however, that any other suitable component may also be included in the apparatus 100. The integrated circuit 102 may include one or more processors that may be a host central processing unit (CPU) having one or multiple cores, a discrete graphic processing unit (GPU), an integrated GPU, a general processor (e.g., APU, accelerated processing unit; GPGPU, general-purpose computing on GPU), or any suitable combination thereof or any other suitable processor.

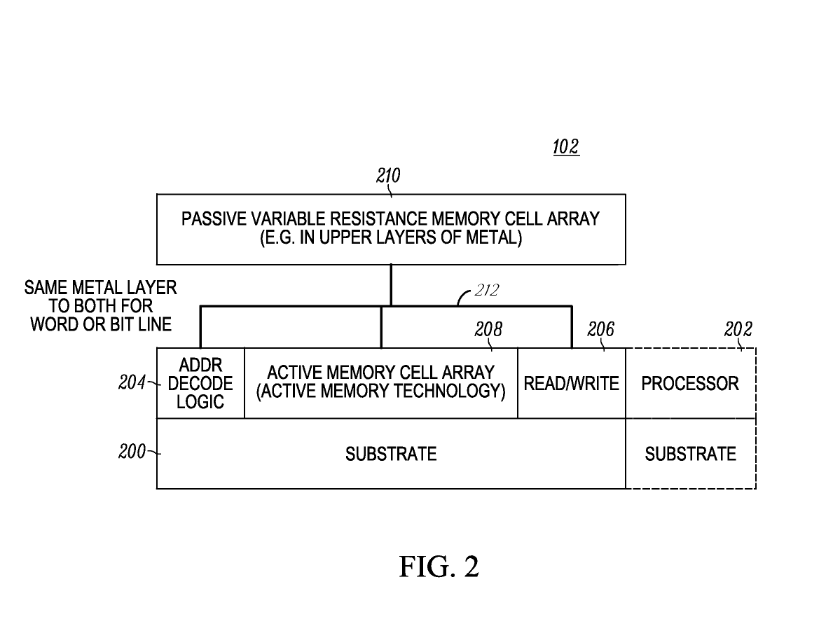

FIG. 2 illustrates a cross-sectional view of one example of integrated circuit 102. In this example, the integrated circuit 102 may include a layer of single-crystal silicon as the substrate 200. In other examples, the substrate 200 may be germanium, silicon on insulator (SOI) such as SiO₂ based SOI and silicon on sapphire, compound semiconductor such as GaAs, GaN to name a few, organic semiconductor, or any other suitable semiconductor material. The integrated circuit 102, in this example shows memory control logic which, in the exemplary embodiments may include both or either of address decode logic 204 and data read/write logic 206, formed on a top side of the substrate 200. The integrated circuit 102 may also optionally include processor 202. An active memory cell array 208 is also formed on the substrate 200. The integrated circuit 102 also includes a passive variable resistance memory cell array 210 located above the active memory cell array 208 and a metal layer 212, also referred to as an electrode layer. The metal layer 212 is interposed between the active memory cell array 208 and the passive variable resistance memory cell array 210 and is configured to provide shared wordlines or bitlines for both the active memory cell array 206 and the passive variable resistance memory cell array 210.

The processor 202, active memory cell array 208 and memory control logic include active semiconductor devices that are capable of electrically controlling electron flow, such as but not limited to, bipolar or field effect transistors (FET), semiconductor controlled rectifiers (SCR), or triode for alternating current (TRIAC), to name a few. The processor 202 and memory control logic may also include passive devices that are incapable of controlling current by means of another electrical signal, such as but not limited to resistors, capacitors, inductors, transformers, transmission lines, or any other suitable passive device. In a preferred example, the processor 202, active memory cell array 208 and memory control logic mainly include active CMOS circuits and passive devices (e.g. metal interconnections) constructed in the surface of a thin single-crystal silicon substrate. As noted above. the processor, if employed may include at least one of a CPU having one or multiple cores, a discrete or integrated GPU, an APU, a GPGPU, and any other suitable logic.

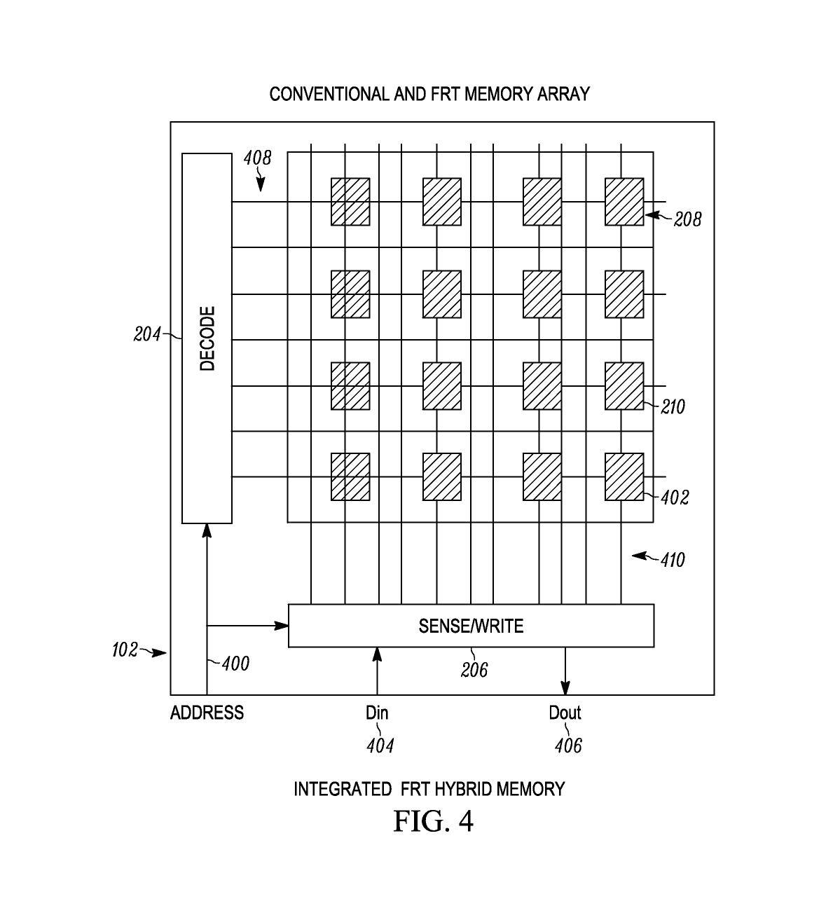

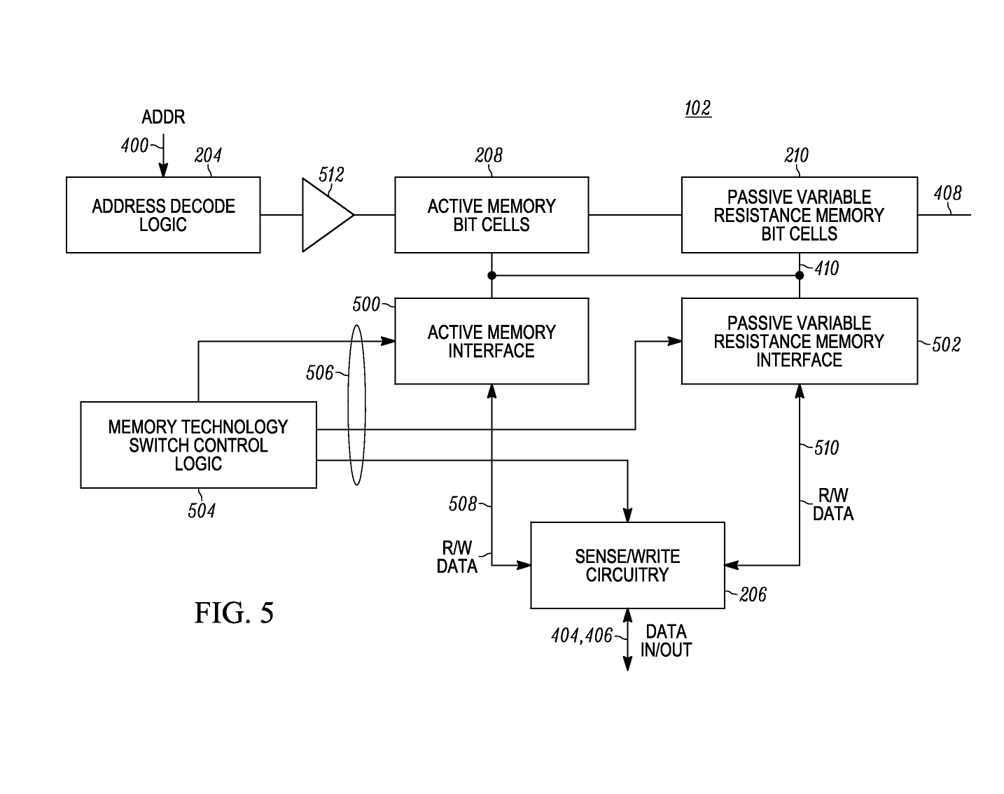

As shown, the passive variable resistance memory cell array 210 is positioned above the active memory cell array 208 and is configured to share at least the same address decode logic 204 and bit lines or word lines as the active memory cell array 208 to effect an address decode operation. The shared metal layer 212 interposed between the passive variable resistance memory cell array and the active memory cell array serves as a common word and/or bit line for both the active memory cell array and the passive variable resistance memory cell array. To provide additional power savings and smaller real estate improvements as well as cost improvements, the passive variable resistance memory cell array 210 is configured to share the data read logic and data write logic 206 with the active memory cell array 208 (discussed further below with respect to FIGS. 4 and 5). In some designs, it may be useful to show bit lines but not word lines because of the size difference in one direction.

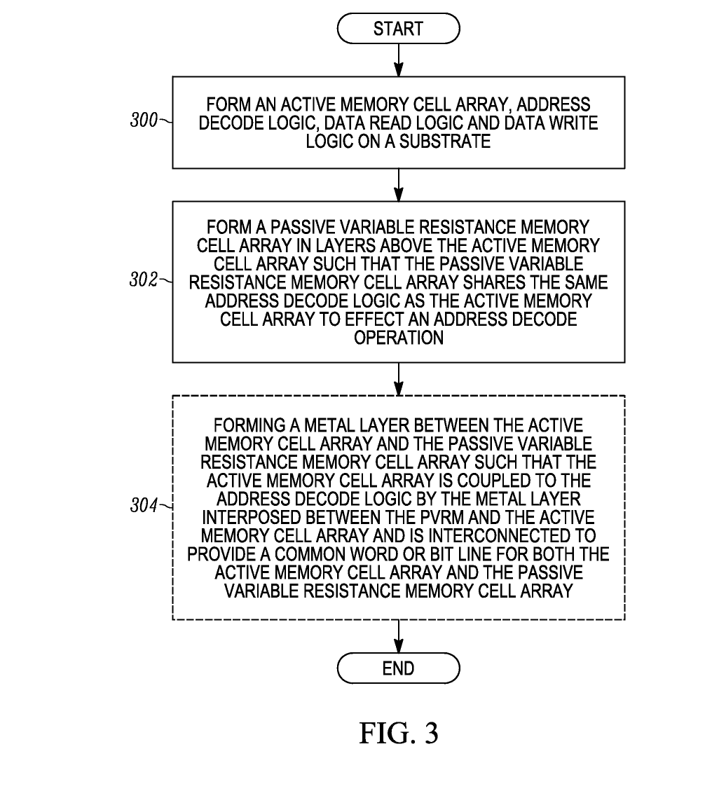

FIG. 3 illustrates one example of a method of making the integrated circuit 102. As shown in block 300, the method includes forming an active memory cell array 208, address decode logic 204 and data read logic and data write logic 206 on a substrate 200. This may be done using conventional fabrication processes as known in the art. The method also includes as shown in block 302, forming the passive variable resistance memory cell array 210 in layers above the active memory cell array 208 such that the passive variable resistance memory cell array 210 is configured to share at least the same address decode logic 204 as the active memory cell array 208, to effect an address decode operation. In this example, word lines and bit lines are also configured to be shared. In this example, this includes employing the same metal layer 212 positioned above the active memory cell array and below the passive variable resistance memory cell array 210. The fabrication of the passive variable resistance memory cell array 210 is further set forth below. As shown in block 304, the method includes forming the metal layer 212 between the active memory cell array 208 and the passive variable resistance memory cell array 210 such that the active memory cell array 208 is coupled to the address decode logic 204 by the metal layer 212. This may be done using conventional metal deposition techniques. The method also includes fabricating the metal layer 212 to provide an interconnect between the passive variable resistance memory cell array 210 and the active memory cell array 208 to provide a common word and/or bit line for both differing technology types of memory cell arrays.

The method also includes configuring the passive variable resistance memory cell array to share at least portions of the data read logic and data write logic 206 with the active memory cell array 208 as shown in FIG. 5. It may also be useful to share interface circuits as well.

Referring to FIGS. 4 and 5, the integrated circuit 102 is shown diagrammatically and in block diagram form. The illustration of FIG. 4 may be considered a top view of the integrated circuit which shows functional blocks illustrating the address decode logic and the data read/write logic 206. As illustrated, address information 400 is provided to the address decode logic 204 and to the read/write logic 206. The passive variable resistance memory cell array 210 is shown to include a plurality of passive variable resistance memory cells 402 located above the active memory cell array 208. As illustrated, input data 404 is provided to the read/write logic 206 and output data 406 is provided, for example, in response to a read request. In addition, the metal layer 212 is illustrated to include common word lines 408 common to both the passive variable resistance memory cell array 210 and the active memory cell array 208. The metal layer 212 is also shown to include common bit lines 410 that are common to both the passive variable resistance memory cell array 210 and the active memory cell array 208.

Also referring to FIG. 5, the integrated circuit 102 may include active memory interface logic 500 coupled to the active memory bit cells and the active memory cell array 208. The integrated circuit also includes passive variable resistance memory interface logic 502 that is operatively coupled to the passive variable resistance memory cell array 210 and in particular the passive variable resistance memory bit cells therein. As shown, the active memory interface logic and the passive variable resistance memory interface logic 500 and 502 are coupled to both the active memory bit cells and the passive variable resistance memory bit cells via common bit lines 410 in the metal layer 212 located above the active memory cell array. The integrated circuit also includes memory technology switch control logic 504 to be controlled, for example, by corresponding control registers that are written to by a processor or any other suitable control logic to select which of the active memory cell array 208 or the passive variable resistance memory cell array 210 is being read from or written to. The memory technology switch control logic 504 therefore controls the active memory interface logic 500, the passive variable resistance memory interface logic 502, the data read logic and data write logic 206 via suitable control information 506 to selectively provide read/write access to either the active memory cell array 208 or the passive variable resistance memory cell array 210.

Arrows 508 and 510 represent the data that is read from or written to the differing memory technologies. For example, read or write data 508 is read from or written to active memory cell 208 whereas the read or write data 510 is read from or written to the passive variable resistance memory cell array 210.

The processor 202, if utilized, may issue read or write commands that are then executed to control the address decode logic and read and write logic to suitably access either or both of the passive variable resistance memory cell array 210 or the active memory cell array 208 depending on which memory technology has been selected by the switch control logic 504. By way of example, in operation the processor may determine which of the two memory structures to utilize for given data depending on, for example, the amount of data that needs to be read or written or the type of data. For example, the processor may provide a very high bandwidth copy operation between the two memory structures controlling the memory technology switch control logic 504 to select a read operation from the active memory cell array 208 and cause the read data to be written to which then may cause the memory technology switch control logic 504 to select the passive variable resistance memory cell array 210 to be active so that the read data can then be written to the passive variable resistance memory bit cells to effect a high bandwidth copy operation.

In an alternative embodiment, depending upon the software application being executed by the processor, the passive variable resistance memory cell array may be selected via the memory technology switch control logic 504 to be active so that reads and writes are provided to the passive variable resistance memory cell array for information that requires a non-volatile state. The processor may then control the memory switch control logic 504 to deactivate the passive variable resistance memory cell array operation and activate the active memory cell operation so that data is read to and written from the active memory cell arrays.

Referring also to FIG. 5, the method of fabrication may include, for example, forming the active memory interface logic 500 to be coupled to the active memory cell array 208, forming the passive variable resistance memory interface logic 502 to be coupled to the passive variable resistance memory cell array 210, such as through the metal layer 212. It will be recognized that the metal layer 212 may include a plurality of metal layers therein that are interconnected through vias or any other suitable interconnects. The method also includes forming the memory technology switch control logic 504 such that it is operative to control the active memory interface logic 500, the passive variable resistance memory interface 502 and the data read and write logic 206 to selectively provide read/write access to either the active memory cell array 208 or the passive variable resistance memory cell array 210.

The active memory interface logic 500 may include logic, for example, that provides bit level access to active memory bit cells as known in the art. Similarly, the passive variable resistance memory interface 502 is logic that provides, for example, bit level access to passive variable resistance memory bit cells in the passive variable resistance memory cell array 210. It will be recognized, however, that multiple bit access or any other suitable access may be provided. The logic may include suitably configured transistors, state machines or any suitable logic structure as known in the art.

The electrode layer 212 may be formed using any suitable metal or semiconductor materials such as but not limited to platinum, copper, gold, aluminum, titanium, iridium, iridium oxide, ruthenium, or silver, by thin-film deposition techniques such as CVD, thermal evaporation, sputtering, MBE, atomic layer deposition or electroplating. The passive variable resistance memory cell array 210 may be formed by thin-film deposition techniques such as CVD, thermal evaporation, sputtering, MBE, electroplating, spin-coating, or any other suitable techniques. The material of the passive variable resistance memory cell array may be any suitable variable resistance material that is capable of storing state by resistance. Depending on the specific type of passive variable resistance memory, the material of the passive variable resistance memory layer may include, for example, one or more thin-film oxides (e.g., TiO₂, SiO₂, NiO, CeO₂, VO₂, V₂O₅, Nb₂O₅, Ti₂O₃, WO₃, Ta₂O₅, ZrO₂, IZO, ITO, etc.) for memristors, chalcogenide for phase-change memory, and ferromagnetic materials (e.g., CoFeB incorporated in MgO) for magnetoresistive memory.

It is known in the art that memory may be implemented by an array of memory cells. Each memory cell of the array includes a memory region as a place to store state, which represents one bit of information. In order to access each memory cell, the array of memory is organized by rows and columns, and the intersection point of each row-column pair is a memory region. The rows are also called word lines, whereas the columns are named bit lines.

In this example embodiment, each passive variable resistance memory cell (e.g. one bit) may be a memristor of any suitable design. However, any suitable passive variable resistance memory technology may be employed. The passive variable resistance memory cell array 210 in this example embodiment, is implemented as a memory layer of memristor passive variable-resistive memory cells (e.g. each 1 bit) and may be of any suitable design. Since a memristor includes a memory region (e.g., a layer of TiO₂) between two metal contacts (e.g., platinum wires), memristors could be accessed in a cross point array style (i.e., crossed-wire pairs) with alternating current to non-destructively read out the resistance of each memory cell. A cross point array is an array of memory regions that can connect each wire in one set of parallel wires to every member of a second set of parallel wires that intersects the first set (usually the two sets of wires are perpendicular to each other, but this is not a necessary condition). The memristor disclosed herein may be fabricated using a wide range of material deposition and processing techniques. One example is disclosed in corresponding U.S. Patent Application Publication No. 2008/0090337, having a title “ELECTRICALLY ACTUATED SWITCH”, which is incorporated herein by reference.

In this example, first, a lower electrode is fabricated above the actual memory cell array 208 using conventional techniques such as photolithography or electron beam lithography, or by more advanced techniques, such as imprint lithography. This may be, for example, a bottom wire of a crossed-wire pair. The material of the lower electrode may be either metal or semiconductor material, preferably, platinum.

In this example, the next component of the memristor to be fabricated is the non-covalent interface layer, and may be omitted if greater mechanical strength is required, at the expense of slower switching at higher applied voltages. In this case, a layer of some inert material is deposited. This could be a molecular monolayer formed by a Langmuir-Blodgett (LB) process or it could be a self-assembled monolayer (SAM). In general, this interface layer may form only weak van der Waals-type bonds to the lower electrode and a primary layer of the memory region. Alternatively, this interface layer may be a thin layer of ice deposited onto a cooled substrate. The material to form the ice may be an inert gas such as argon, or it could be a species such as CO₂. In this case, the ice is a sacrificial layer that prevents strong chemical bonding between the lower electrode and the primary layer, and is lost from the system by heating the substrate later in the processing sequence to sublime the ice away. One skilled in this art can easily conceive of other ways to form weakly bonded interfaces between the lower electrode and the primary layer.

Next, the material for the primary layer is deposited. This can be done by a wide variety of conventional physical and chemical techniques, including evaporation from a Knudsen cell, electron beam evaporation from a crucible, sputtering from a target, or various forms of chemical vapor or beam growth from reactive precursors. The film may be in the range from 1 to 30 nanometers (nm) thick, and it may be grown to be free of dopants. Depending on the thickness of the primary layer, it may be nanocrystalline, nanoporous or amorphous in order to increase the speed with which ions can drift in the material to achieve doping by ion injection or undoping by ion ejection from the primary layer. Appropriate growth conditions, such as deposition speed and substrate temperature, may be chosen to achieve the chemical composition and local atomic structure desired for this initially insulating or low conductivity primary layer.

The next layer is a dopant source layer, or a secondary layer, for the primary layer, which may also be deposited by any of the techniques mentioned above. This material is chosen to provide the appropriate doping species for the primary layer. This secondary layer is chosen to be chemically compatible with the primary layer, e.g., the two materials should not react chemically and irreversibly with each other to form a third material. One example of a pair of materials that can be used as the primary and secondary layers is TiO₂ and TiO₂₋ₓ, respectively. TiO₂ is a semiconductor with an approximately 3.2 eV bandgap. It is also a weak ionic conductor. A thin film of TiO₂ creates the tunnel barrier, and the TiO₂₋ₓ forms an ideal source of oxygen vacancies to dope the TiO₂ and make it conductive.

Finally, the upper electrode in the passive variable resistance memory layer is fabricated on top of the secondary layer in a manner similar to which the lower electrode was created. This may be, for example, a top wire of a crossed-wire pair. The material of the lower electrode may be either metal or semiconductor material, for example, platinum. If the memory cell is in a cross point array style, an etching process may be necessary to remove the deposited memory region material that is not under the top wires in order to isolate the memory cell. It is understood, however, that any other suitable material deposition and processing techniques may be used to fabricate memristors for the passive variable-resistive memory. It will also be recognized that any other suitable passive variable resistance technology may be employed as mentioned above or that the order of operation may be rearranged in any suitable manner.

It will be understood that PVRM is a term used to describe any memory technology that stores state in the form of resistance instead of charge. That is, PVRM technologies use the resistance of a cell to store the state of a bit, in contrast to charge-based memory technologies that use electric charge to store the state of a bit. PVRM is referred to as being passive due to the fact that it does not require any active semiconductor devices, such as transistors, to act as switches. These types of memory are said to be “non-volatile” due to the fact that they retain state information following a power loss or power cycle. Passive variable resistive memory is also known as resistive non-volatile random access memory (RNVRAM or RRAM).

Examples of PVRM include, but are not limited to, Ferroelectric RAM (FeRAM), Magnetoresistive RAM (MRAM), Memristors, Phase Change Memory (PCM), and Spin-Torque Transfer MRAM (STT-MRAM). While any of these technologies may be suitable for use in the IC 102 disclosed herein, PCM, memristors, and STT-MRAM are contemplated as providing an especially nice fit and are therefore discussed below in additional detail.

Phase change memory (PCM) is a PVRM technology that relies on the properties of a phase change material, generally chalcogenides, to store state. Writes are performed by injecting current into the storage device, thermally heating the phase change material. An abrupt shutoff of current causes the material to freeze in an amorphous state, which has high resistivity, whereas a slow, gradual reduction in current results in the formation of crystals in the material. The crystalline state has lower resistance than the amorphous state; thus a value of 1 or 0 corresponds to the resistivity of a cell. Varied current reduction slopes can produce in-between states, allowing for potential multi-level cells. A PCM storage element consists of a heating resistor and chalcogenide between electrodes, while a PCM cell is comprised of the storage element and an access transistor.

Memristors are commonly referred to as the “fourth circuit element,” the other three being the resistor, the capacitor, and the inductor. A memristor is essentially a two-terminal variable resistor, with resistance dependent upon the amount of charge that passed between the terminals. Thus, a memristor's resistance varies with the amount of current going through it, and that resistance is remembered even when the current flow is stopped.

Spin-Torque Transfer Magnetoresistive RAM (STT-MRAM) is a second-generation version of MRAM, the original of which was deemed “prototypical” by the International Technology Roadmap for Semiconductors (ITRS). MRAM stores information in the form of a magnetic tunnel junction (MTJ), which separates two ferromagnetic materials with a layer of thin insulating material. The storage value changes when one layer switches to align with or oppose the direction of its counterpart layer, which then affects the junction's resistance. Original MRAM required an adequate magnetic field in order to induce this change. This was both difficult and inefficient, resulting in impractically high write energy. STT-MRAM uses spin-polarized current to reverse polarity without needing an external magnetic field. Thus, the STT technique reduces write energy as well as eliminating the difficult aspect of producing reliable and adequately strengthen magnetic fields. However, STT-MRAM, like PCM, requires an access transistor and thus its cell size scaling depends on transistor scaling.

Also, integrated circuit fabrication systems (e.g., wafer fabrication system) are known that create wafers with integrated circuits based on executable instructions stored on a computer readable medium such as but not limited to CDROM, RAM, other forms of ROM, hard drives, distributed memory, etc. are produced by an integrated circuit design system (e.g., work station). The instructions may be represented by any suitable language such as but not limited to hardware descriptor language (HDL), Verilog or other suitable language. As such, the logic and circuits described herein may also be produced as integrated circuits by such fabrication systems using the non-transitory computer readable medium with instructions stored therein. For example, an integrated circuit with the aforedescribed logic and structure may be created using such integrated circuit fabrication systems. The computer readable medium stores instructions executable by one or more integrated circuit design systems that causes the one or more integrated circuit design systems to fabricate an integrated circuit. The designed integrated circuit includes address decode logic, data read logic, data write logic, an active memory cell array coupled to the address decode logic, the data read logic and the data write logic and a passive variable resistance memory (PVRM) cell array, positioned above the active memory cell array. The passive variable resistance memory cell array is configured to share at least the same address decode logic as the active memory cell array to effect an address decode operation. The fabricated integrated circuit may also include the other aspects described herein.

Among other advantages, the passive variable resistance memory cell arrays reside above the conventional active memory cell arrays and the two different memory technologies may share the address decoder, word line drivers 512 and read/write logic 206 as well as address decode logic 204 bit lines and/or word lines. The passive variable resistance memory cells are located in layers above the metal layer 212 and above the active memory cell array. The passive variable resistance memory cell array 210 does not employ active transistors and therefore may provide an improved hybrid memory fabrication structure. Other advantages will be recognized by those of ordinary skill in the art.

The above detailed description of the invention and the examples described therein have been presented for the purposes of illustration and description only and not by limitation. It is therefore contemplated that the present invention cover any and all modifications, variations or equivalents that fall within the spirit and scope of the basic underlying principles disclosed above and claimed herein.

What is claimed is:

1. An integrated circuit comprising:
memory control logic;
an active memory cell array coupled to the memory control logic; and
a passive variable resistance memory (PVRM) cell array configured to share at least a portion of the memory control logic as the active memory cell array.

2. The IC of claim 1 wherein the memory control logic comprises at least one of address decode logic, data read logic and data write logic.

3. The IC of claim 1 wherein the PVRM is positioned above the active memory cell array.

4. The IC of claim 1 wherein the active memory cell array and the passive variable resistance memory cell array is coupled to the address decode logic by a metal layer interposed between the PVRM and the active memory cell array, serving as a common word and/or bit line for both the active memory cell array and the passive variable resistance memory cell array.

5. The IC of claim 1 wherein the passive variable resistance memory cell array is configured to share the data read logic and the data write logic with the active memory cell array.

6. The integrated circuit of claim 1 comprising:
active memory interface logic operatively coupled to the active memory cell array;
passive variable resistance memory interface logic operatively coupled to the passive variable resistance memory cell array; and
memory technology switch control logic, operative to control the active memory interface logic, the passive variable resistance memory interface logic, the data read logic and the data write logic, to selectively provide read/write access to either the active memory cell array or the passive variable memory cell array.

7. The integrated circuit of claim 4 comprising a processor and substrate on which the processor, address decode logic, data read logic, data write logic, and active memory cell array are formed.

8. A method of making an integrated circuit comprising:
forming an active memory cell array, address decode logic, data read logic and data write logic on a substrate; and
forming a passive variable resistance memory cell array in layers above the active memory cell array such that the passive variable resistance memory cell array is configured to share at least the same address decode logic as the active memory cell array to effect an address decode operation.

9. The method of claim 8 comprising forming a metal layer between the active memory cell array and the passive variable resistance memory cell array such that the active memory cell array is coupled to the address decode logic by the metal layer interposed between the PVRM and the active memory cell array and is interconnected to provide a common word or bit line for both the active memory cell array and the passive variable resistance memory cell array.

10. The method of claim 8 comprising configuring the passive variable resistance memory cell array to share at least portions of the data read logic and the data write logic with the active memory cell array.

11. The method of claim 8 comprising:
forming active memory interface logic operatively coupled to the active memory cell array;
forming passive variable resistance memory interface logic operatively coupled to the passive variable resistance memory cell array;
forming memory technology switch control logic, operative to control the active memory interface logic, the passive variable resistance memory interface logic, the data read logic and the data write logic, to selectively provide read/write access to either the active memory cell array or the passive variable memory cell array.

12. The method of claim 8 comprising forming a processor on the substrate in layers below the passive variable resistance memory cell array.

13. A storage medium that comprises executable instructions thereon that when executed by an integrated circuit fabrication system, causes the system to form an integrated circuit that comprises:
address decode logic;
data read logic;
data write logic;
an active memory cell array coupled to the address decode logic, the data read logic and the data write logic; and
a passive variable resistance memory (PVRM) cell array positioned above the active memory cell array and wherein the passive variable resistance memory cell array is configured to share at least the same address decode logic as the active memory cell array to effect an address decode operation.

14. The storage medium of claim 13 comprising executable instruction stored therein that when executed by the integrated circuit fabrication system causes the system to fabricate the integrated circuit such that the active memory cell array and the passive variable resistance memory cell array is coupled to the address decode logic by a metal layer interposed between the PVRM and the active memory cell array, serving as a common word or bit line for both the active memory cell array and the passive variable resistance memory cell array.

15. The storage medium of claim 13 comprising executable instruction stored therein that when executed by the integrated circuit fabrication system causes the system to fabricate the integrated circuit such that the passive variable resistance memory cell array shares at least portions of the data read logic and the data write logic with the active memory cell array.

16. The storage medium of claim 13 comprising executable instruction stored therein that when executed by the integrated circuit fabrication system causes the system to fabricate the integrated circuit to comprise:
active memory interface logic operatively coupled to the active memory cell array;
passive variable resistance memory interface logic operatively coupled to the passive variable resistance memory cell array; and
memory technology switch control logic, operative to control the active memory interface logic, the passive variable resistance memory interface logic, the data read logic and the data write logic, to selectively provide read/write access to either the active memory cell array or the passive variable memory cell array.

17. The storage medium of claim 13 comprising executable instruction stored therein that when executed by the integrated circuit fabrication system causes the system to fabricate the integrated circuit with a processor on a substrate on which address decode logic, data read logic, data write logic, and active memory cell array are formed.

18. An apparatus comprising:
a display;
an integrated, operatively coupled to the display, the integrated circuit comprising:
address decode logic;
data read logic;
data write logic;
an active memory cell array coupled to the address decode logic, the data read logic and the data write logic; and
a passive variable resistance memory (PVRM) cell array, positioned above the active memory cell array and wherein the passive variable resistance memory cell array is configured to share at least the same address decode logic as the active memory cell array to effect an address decode operation.

19. The apparatus of claim 18 wherein the wherein the active memory cell array and the passive variable resistance memory cell array is coupled to the address decode logic by a metal layer interposed between the PVRM and the active memory cell array, serving as a common word and/or bit line for both the active memory cell array and the passive variable resistance memory cell array.

20. The apparatus of claim 18 wherein the passive variable resistance memory cell array is configured to share the data read logic and the data write logic with the active memory cell array.

21. The apparatus of claim 18 wherein the integrated circuit comprises:
active memory interface logic operatively coupled to the active memory cell array;
passive variable resistance memory interface logic operatively coupled to the passive variable resistance memory cell array; and
memory technology switch control logic, operative to control the active memory interface logic, the passive variable resistance memory interface logic, the data read logic and the data write logic, to selectively provide read/write access to either the active memory cell array or the passive variable memory cell array.

22. The apparatus of claim 21 wherein the passive variable resistance memory interface logic is comprised of memristor memory cells.
